(19) United States
(12) Patent Application Publication
(10) Pub. No.: US 2016/0365705 A1
(43) Pub. Date: Dec. 15, 2016

(54) Semiconductor nano/microlaser tuning by strain engineering

(71) Applicant: Sandia Corporation, Albuquerque, NM (US)

(72) Inventors: George T. Wang, Albuquerque, NM (US); Sheng Liu, Albuquerque, NM (US)

(21) Appl. No.: 14/737,222

(22) Filed: Jun. 11, 2015

(51) Int. Cl. H01S 5/32; H01S 5/327; H01S 5/20; H01S 5/323

(52) U.S. Cl. CPC H01S 5/3201; H01S 5/32341; H01S 5/327; H01S 5/20

(57) ABSTRACT

A method for tuning the lasing wavelength of a semiconductor nano/microlaser uses mechanical strain to change the bandgap of the semiconductor material and the lasing wavelength. The method enables broad, dynamic, and reversible spectral tuning of single nano/microlasers with subnanometer resolution.

### STATEMENT OF GOVERNMENT INTEREST

This invention was made with Government support under contract no. DE-AC04-94AL85000 awarded by the U. S. Department of Energy to Sandia Corporation. The Government has certain rights in the invention.

### FIELD OF THE INVENTION

The present invention relates to semiconductor lasers and, in particular, to method to tune semiconductor nano- and micro-lasers by strain engineering.

### BACKGROUND OF THE INVENTION

Semiconductor nanowires (NWs) have been explored as nanophotonic building blocks due to their compact sizes, low power consumption and ultrafast modulation bandwidth. See R. Yan et al., Nat Photon 3, 569 (2009). Recently, semiconductor NW-based solar cells, high efficiency solid-state lighting, photodetectors, nonlinear optical conversion, and all-optical active switching have been demonstrated. See J. Wallentin et al., Science 339, 1057 (2013); B. Tian et al., Nature 449, 885 (2007); J. B. Baxter and E. S. Aydil, Applied Physics Letters 86, 053114 (2005); P. Krogstrup et al., Nat Photon 7, 306 (2013); J. W. Wierer, Jr. et al., Nanotechnology 23, 194007 (2012); J. Y. Tsao et al., Advanced Optical Materials 2, 809 (2014); M. S. Gudiksen et al., Nature 415, 617 (2002); H. Kind et al., Advanced Materials 14, 158 (2002); C. Soci et al., Nano Letters 7, 1003 (2007); Y. Nakayama et al., Nature 447, 1098 (2007); M. A. Foster et al., Optics Express 16, 1300 (2008); and B. Piccione et al., Nat Nano 7, 640 (2012).

Semiconductor NWs have also attracted interest as nanoscale lasers, as the NW can serve as a Fabry-Perot cavity with the end facets providing optical feedback and full gain media of the whole NW. NW lasers have been demonstrated in several materials systems under optical pumping. See Y. Ma et al., Adv. Opt. Photon. 5, 216 (2013); and D. Saxena et al., Nat Photon 7, 963 (2013). Of particular interest are NW lasers that could be tuned at precise wavelengths and also over a wide wavelength range, which would enable their use in variable applications such as optical communications, sensing, signal processing, spectroscopy analysis, and so forth. Most simply, “tunable” wavelength lasing in NWs has been previously achieved by varying the composition of different NWs to change their bandgap. See Y. Ma et al., Adv. Opt. Photon. 5, 216 (2013); A. Pan et al., Nano Letters 9, 784 (2009); and F. Qian et al., Nat Mater 7, 701 (2008). Liu et al. were able to observe ˜30 nm of wavelength tuning in NWs of different lengths, based on the intrinsic self-absorption of the gain media. See X. Liu et al., Nano Letters 13, 1080 (2013). Tunable lasing was also achieved using a surface plasmon polariton enhanced Burstein-Moss effect, wherein different NWs placed on substrates with decreasing dielectric layer thickness resulted in a blue shift of the lasing wavelength. See X. Liu et al., Nano Letters 13, 5336 (2013). Wavelength selection was also demonstrated by cutting axially composition-graded CdSSe NWs at specific points along its length, to change the effective bandgap of the cut NW laser segment. See Z. Yang et al., Nano Letters 14, 3153 (2014). NW photonic crystals lasers have also been fabricated wherein the lasing wavelength can be controlled via the NW pitch (lattice constant) and diameter of each array or pixel. See J. B. Wright et al., Sci. Rep. 3, 2982 (2013); and I. Shusuke et al., Applied Physics Express 4, 055001 (2011). However, in all of the above approaches, the lasing wavelength of each individual NW (or NW coupled to a substrate) or NW array is already fixed and not tunable in the true sense—selecting different lasing wavelengths requires using different NW/NW array lasers.

Therefore, a need remains for a nano- or micro-laser that can be actively tuned at precise wavelengths over a wide wavelength range.

### SUMMARY OF THE INVENTION

The present invention is directed to a method for tuning the lasing wavelength of a semiconductor nano/microlaser by applying a mechanical strain to the nano/microlaser to change the bandgap of the semiconductor material and the lasing wavelength. The semiconductor material can comprise any optically emitting semiconductor, including III-V and II-VI compound semiconductors, such as (Al)(In)(Ga)N, (Al)(In)(Ga)As, (Al)(In)(Ga)P, (Al)(In)(Ga)Sb, alloys thereof, and ZnO. The mechanical strain can comprise hydrostatic pressure applied using a diamond anvil cell, piston-cylinder device, multi-anvil cell, or embossing machine. Alternatively, the mechanical strain can comprise tensile or compressive strain applied using a microelectromechanical or piezoelectric system. The method enables broad, dynamic, and reversible spectral tuning of single nano/microlasers with subnanometer resolution.

As an example of the invention, continuous, dynamic, reversible, and widely tunable lasing from 367 to 337 nm from a single GaN NW was demonstrated by applying hydrostatic pressures up to ˜7 GPa. The GaN NW lasers, with heights of 4-5 μm and diameters ˜140 nm, were fabricated using a lithographically defined two-step, top-down technique. The wavelength tuning was caused by an increasing Γ direct bandgap of GaN with increasing pressure and was precisely controllable to subnanometer resolution. The observed pressure coefficients of the NWs were ˜40% larger compared with larger GaN microstructures fabricated from the same material or from reported bulk GaN values, indicating a nanoscale-related effect that significantly enhances the tuning range. The method can be applied to other semiconductor nano/microlasers to potentially achieve full spectral coverage from the UV to IR.

### BRIEF DESCRIPTION OF THE DRAWINGS

The detailed description will refer to the following drawings, wherein like elements are referred to by like numbers.

FIG. 1 is a schematic illustration of a nanowire laser.

FIG. 2 is a schematic illustration of the change in the direct bandgap energy of a semiconductor by strain engineering.

FIGS. 3(a)-(c) are scanning electron microscope (SEM) images of GaN NW laser fabrication using a two-step “top-down” etching process. FIG. 3(a) is an SEM image of periodic Ni dots a dry etch mask patterned on top of a GaN epilayer by e-beam lithography followed by metal deposition and lift-off. FIG. 3(b) is a SEM image of GaN posts after dry etch with tapered shape and rough side-walls. FIG. 3(c) is an SEM image of GaN NWs after wet etch. The scale bars correspond to 2 μm.

FIG. 4 is a schematic illustration of the application of hydrostatic pressure on GaN NWs using a diamond anvil cell. The inset shows a band diagram for wurtzite GaN around the Γ Brillouin zone at ambient pressure.

FIG. 5 is a schematic illustration of a of a micro-photoluminescence (μ-PL) system.

FIG. 6 is a graph of PL spectra of single GaN NW at different hydrostatic pressures.

FIG. 7 is a graph of the GaN (NWs and bulk) bandgap as a function of applied pressure. The inset is a SEM image of GaN micropillars. The scale bar corresponds to 5 μm.

FIG. 8 is a graph of PL spectra versus pump laser intensity of a single GaN NW laser at ambient.

FIG. 9 is a graph of the lasing spectra of a single GaN NW at different pressures showing ˜30 nm wavelength tuning.

FIG. 10 is a graph of light-out versus pump power curves measured from the single GaN NW at pressure of ambient, 1 GPa, 1.3 GPa, 2.4 GPa. The inset is the summary of the NW's lasing thresholds at different pressures.

FIGS. 11(a) and (b) show the results of FDTD simulations. FIG. 11(a) is a graph of the HE₁₁ mode confinement factor as a function of environmental refractive index. The inset shows the electric field intensity profile of HE₁₁ mode supported in a 140 nm diameter GaN NW lying on a diamond surface. FIG. 11(b) is a graph of the NW end facets' reflectivity for the HE₁₁ mode as a function of the environmental refractive index.

### DETAILED DESCRIPTION OF THE INVENTION

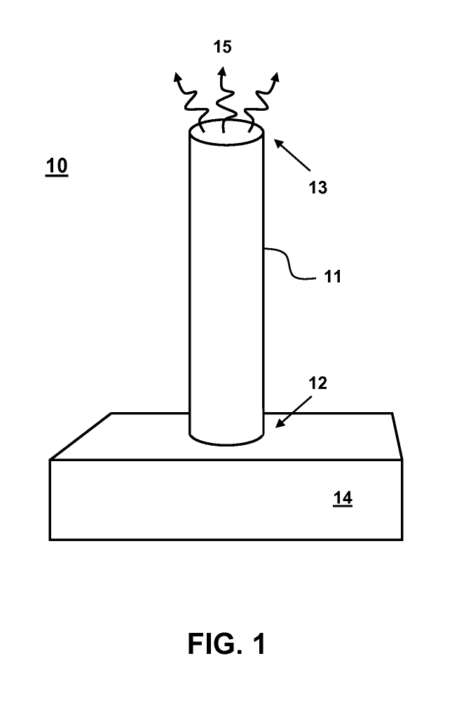

The invention is directed to a method for the dynamic, broadband, and continuous tuning of semiconductor nano/microlasers by utilizing a universal property that a semiconductor's bandgap is a function of strain. FIG. 1 is a schematic illustration of an exemplary single NW laser. This NW laser 10 comprises a nanowire 11 surrounded by air and a simple Fabry-Perot cavity defined by crystalline facet ends 12 and 13 that act as reflecting mirrors for optical confinement. In this illustration, the bottom end facet 12 is defined by the substrate 14, although the NW laser can alternatively be free standing. The optical field propagating along the longitudinal direction is amplified and absorbed inside the NW. Part of the light is reflected back into the cavity from the facets, and the remaining light emits 15 from the top end facet 13. The threshold conditions for the NW laser are therefore determined by the balance between the round-trip gain and loss inside the cavity. See S. Arafin et al., J. Nanophotonics 7, 074599 (2013).

For the purpose of this invention, a nano/microlaser (i.e., a nano- or micro-laser) can typically have a cross-sectional (short) dimension of less than about 15 microns and, preferably, less than several hundreds of nanometers with a length that can vary from a few hundred nanometers to hundreds of microns. In general, the nano/microlaser can have a circular, hexagonal, triangular, or rectangular cross-sectional area and can be solid or hollow (e.g., tubular). For the purpose of this invention, a nano/microlaser will be understood to include any type of nano- or microstructure that is capable of lasing, including nano- and micro-wires, belts, columns, rods, tubes, rings, stripes, discs, sheets, etc. A variety of active area configurations can be used, including radial (e.g., core-shell or coaxial) and axial heterostructures. Finally, a variety of III-V or II-VI compound semiconductor material systems can be used, including (Al)(In)(Ga)N, (Al)(In)(Ga)As, (Al)(In)(Ga)P, (Al)(In)(Ga)Sb, alloys thereof, and ZnO systems.

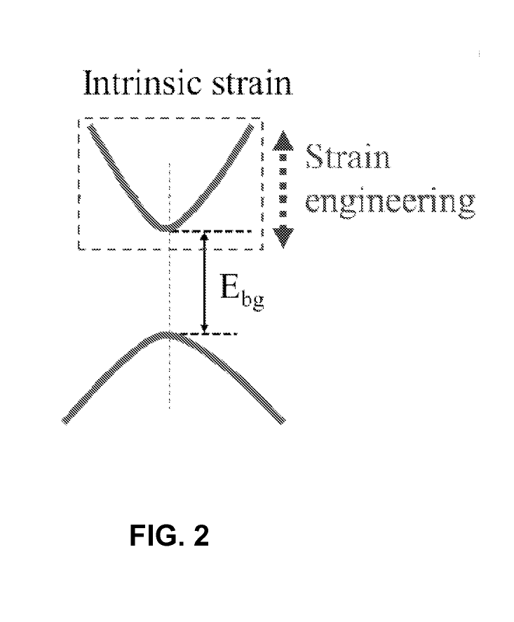

FIG. 2 shows a band diagram for a direct bandgap semiconductor material when no external strain is applied. As external strain is applied, the lattice constant of the semiconductor changes so the bandgap varies. Therefore, the direct bandgap energy can be engineered (i.e., increased or decreased) by applying external strain. For example, a diamond anvil cell (DAC) can be used to increase the environmental pressure surrounding a semiconductor nano/microlaser. Pressure can also be applied by, for example, a piston-cylinder device, multi-anvil cell, or embossing machine. Other strain engineering techniques, such as uniaxial or biaxial tensile and compressive strain applied by microelectromechanical and piezoelectric systems (e.g. pulling, bending, twisting, pushing) can also be used to strain engineer tunable laser sources. See G. Signorello et al., Nano Letters 13, 917 (2012), which is incorporated herein by reference. For example, if the semiconductor laser is piezoelectric, strain can be induced by application of an external electric field. For example, tensile or compressive strain can be applied using thermal-induced expansion and contraction of a microelectromechanical or other system. See K. F. Murphy et al., Nano Letters 14, 3785 (2014), which is incorporated herein by reference. Semiconductor materials exhibit unique pressure-dependent bandgap behavior with some material's bandgaps increasing and other's decreasing with increasing pressure. See A. Jayaraman, Reviews of Modern Physics 55, 65 (1983). This bandgap behavior is caused by the decreased lattice constants determined by the material's bulk modulus. Applied pressure can also induce crystal phase transitions. The method can be applied to members of the III-V or II-VI semiconductor families that have large strain coefficients but do not undergo phase transitions at moderate pressures. For example, over 200 nm wavelength tuning may be achievable in GaAs NW lasers. See G. Franssen et al., Journal of Applied Physics 103, 033514 (2008). With the fast development of nano/microlasers in recent years, it may be possible to achieve full coverage of the spectra from UV to near-IR by using only a few different nano/microlasers, such as GaN, InGaN, AlGaAs, GaAs, InGaAs.

As an example of the invention, the dynamic and continuous tuning of single GaN NW lasers was demonstrated using strain engineering. By applying hydrostatic pressures up to ˜7 GPa, a wide ˜30 nm of reversible wavelength tuning with subnanometer resolution was achieved in a single NW laser. A nanoscale effect was also observed whereby the measured pressure coefficients, i.e. the change in bandgap with pressure, of the GaN NWs was ˜40% higher compared to those of bulk GaN or GaN micropillars.

### Fabrication of GaN NW Lasers

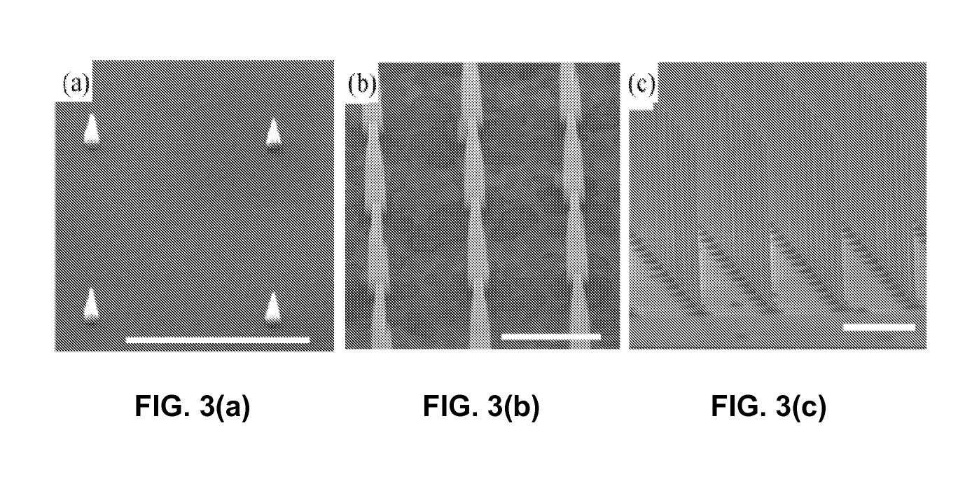

GaN NWs were fabricated using a two-step, dry-plus-wet etch, top-down fabrication method. See U.S. Pat. No. 8,895,337, which is incorporated herein by reference. The method produced uniform and vertically aligned c-axis n-type GaN NW arrays starting from a c-plane (0001) n-type GaN epilayer grown on a sapphire substrate by metal-organic chemical vapor deposition. FIGS. 3(a)-(c) show SEM images of top-down GaN NWs during the fabrication process. Electron-beam lithography was used to accurately pattern dry etch masks consisting of Ni dots to define the wires, as shown in FIG. 3(a). See Q. Li et al., Optics Express 20, 17873 (2012); Q. Li et al., Optics Express 19, 25528 (2011); and J. B. Wright et al., Sci. Rep. 3, 2982 (2013). The Ni-patterned sample underwent a chlorine-based inductive-coupled-plasma (dry) etch to form GaN posts with tapered shape and rough sidewalls, as shown in FIG. 3(b). Next, a crystallographically selective anisotropic KOH-based wet-etch was performed to remove plasma etch induced damage and create non-tapered, smooth-sidewall GaN NWs, as shown in FIG. 3(c). The resulting NWs had straight and smooth side-wall with diameters of ˜140 nm and lengths ˜5 μm. See J. W. Wierer, Jr. et al., Nanotechnology 23, 194007 (2012); Q. Li et al., Optics Express 20, 17873 (2012); and Q. Li et al., Optics Express 19, 25528 (2011). The non-tapered shape is critical such that guided optical modes are supported and well confined all along the NW. The GaN NW length is determined by the duration of the dry-etching (up to a maximum of the GaN epilayer thickness), while the diameter is initially defined by the Ni dot diameter and then shrunk as desired by the wet etch step. Using e-beam lithography defined masks for the two-step, top-down process has the advantages of allowing for arbitrary NW diameter, spacing, and placement. Using lithography defined masks to pattern the dry etch enables better diameter uniformity than previously reported self-assembled silica sphere monolayer masks, due to shorter required wet-etch time (as the Ni dots can be patterned closer to the final desired NW diameter), and also enables the fabrication of more complex cross-sectional structures, such as rectangular and ring shapes. See C. Li et al., in Gallium Nitride Nanotube Lasers, CLEO: 2014, San Jose, Calif., 2014 Jun. 8, 2014; Optical Society of America: San Jose, Calif., 2014; p SW1G.3.

### Spectroscopy of GaN NWs Under Hydrostatic Pressure

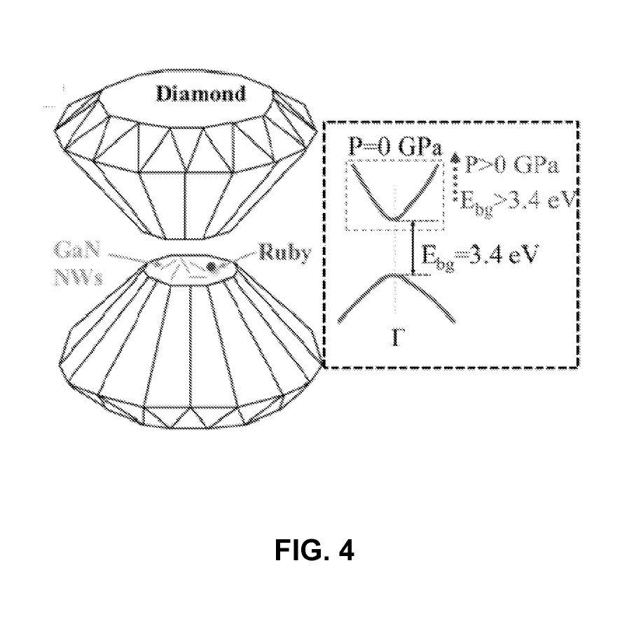

High hydrostatic pressure was applied to the GaN NWs using a diamond-anvil-cell (DAC) with silicone oil as the hydrostatic pressure-transmitting medium. See B. Li et al., Nat Commun 5, 4179 (2014). FIG. 4 is a schematic illustration of the use of a DAC to apply hydrostatic pressure on the GaN NWs. The DAC consisted of two diamonds with flat surfaces facing each other. The diameter of the flat surfaces was 0.6 mm. Either a cotton swab or a needle was used to dry-transfer dozens of free-standing GaN NWs to the surface of one of the diamonds. The NWs were separated enough so they could be individually pumped using a micro-photoluminescence (p-PL) system. A gasket was then placed on top of the other diamond. The gasket had a drilled hole with diameter of ˜0.3 mm forming a pressure chamber. Several ruby micro-spheres were used as standards to monitor the pressure inside the pressure chamber. Next, the pressure chamber was filled with silicone oil to act as a pressure transmission medium. The two diamonds were then pushed together using turning screws to apply high hydrostatic pressure to the GaN NWs.

The inset of FIG. 4 shows the band diagram for wurtzite GaN around the Γ Brillouin zone at ambient pressure. The direct bandgap increases at higher pressure because of the upper shift of conduction band. From the phase transition perspective, the III-nitride materials have the advantage that the direct bandgap to indirect bandgap transition pressure is high (>30 GPa), reportedly even more so for GaN nanostructures (>50 GPa), which expands the range of spectral tuning possible via applied pressure. See H. Xia et al., Physical Review B 47, 12925 (1993); and Z. Dong and Y. Song, Applied Physics Letters 96, 151903 (2010).

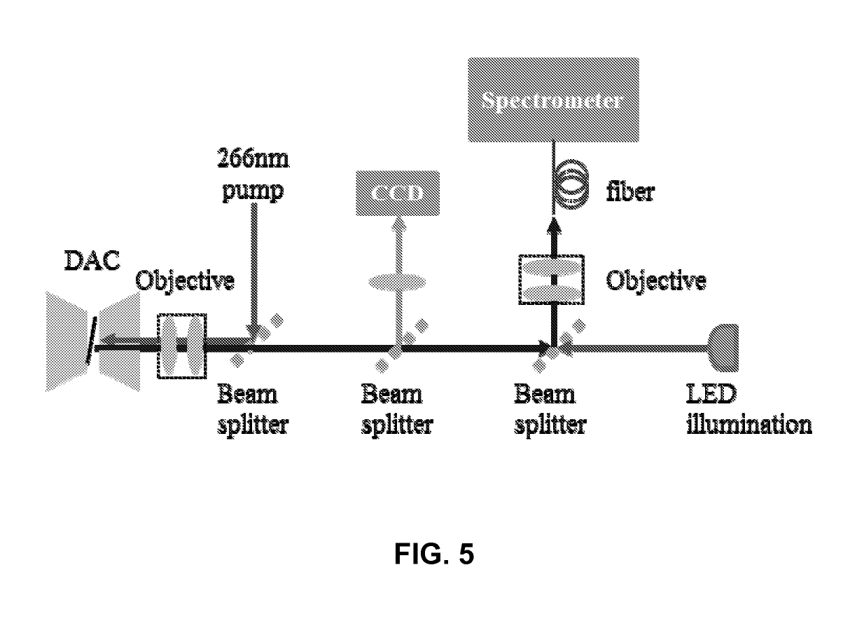

The optical properties of single GaN NWs were measured using the μ-PL system shown in FIG. 5. A λ=266 nm quadrupled YAG pulsed laser was used as an optical pump at room temperature. An LED and a CCD camera were used to illuminate and image through the diamond onto the NWs to make certain the same GaN NW was pumped at the different pressures. The emission from a single NW was collected by an UV objective and focused onto a fiber that transmitted the PL signal into a spectrometer.

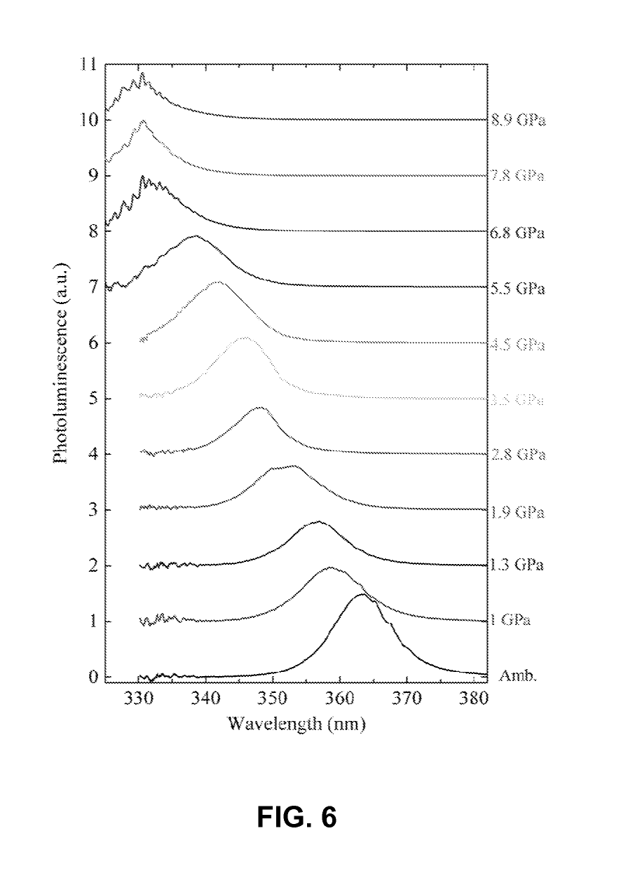

The pressure-dependent PL behavior of a single GaN NWs pumped below the lasing threshold was examined. FIG. 6 shows the PL emission of a single GaN NW at different hydrostatic pressures up to ˜8.9 GPa. All of the PL spectra were collected at the same pump power. A relatively constant PL intensity is observed when pressure is increased, except for an initial decrease from ambient to 1 GPa, which is likely caused by experimental condition changes during the initial compression. This constant PL intensity for GaN NWs is in contrast to GaAs NWs, where a sharp decrease in PL intensity above ˜3 GPa was observed and attributed to a direct to indirect band gap transition under pressure. See I. Zardo et al., ACS Nano 6, 3284 (2012). The noisy PL spectra at wavelengths shorter than 335 nm are caused by the low transmission of the beam splitters at these wavelengths. The PL peak around 363 nm at ambient pressure corresponds to the initial GaN bandgap at 3.42 eV. The change in the near-band edge luminescence transition with pressure was measured to determine the dependence of the bandgap on pressure for the GaN NWs. As the pressure increases, the PL shifts to shorter wavelengths. This blue shift of GaN NW bandgap is caused by the reduction of the lattice spacing at higher pressure described by the Birch-Murnaghan equation-of-state. See G. Franssen et al., Journal of Applied Physics 103, 033514 (2008); M. Ueno et al., Physical Review B 49, 14 (1994); H. Xia et al., Physical Review B 47, 12925 (1993); W. Shan et al., Journal of Applied Physics 85, 8505 (1999); and F. D. Murnaghan, Proceedings of the National Academy of Sciences 30, 244 (1994). The PL blue shift saturates above about 7 GPa at a relatively constant peak energy of ˜3.76 eV (˜330 nm) due to the negative second-order pressure coefficient, as will be described below. Thus, an overall blue shift of ˜0.34 eV (˜35 nm) is observed when the pressure increases from ambient pressure to above 7 GPa. No significant change of the spectral shape or line width of the PL at different pressures is observed.

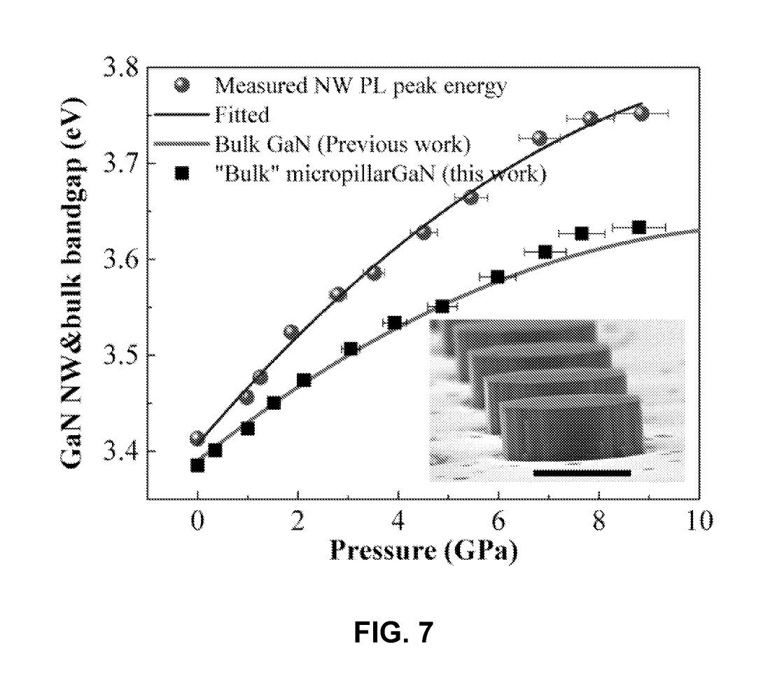

The measured GaN NW bandgap (from FIG. 6) is plotted (circles) as a function of applied pressure in FIG. 7. The data was fit using a second order polynomial function and the extracted pressure coefficients were compared with those of bulk GaN films reported previously. The fitting function for the GaN NWs is:

E_{g}=3.408+6.09×10⁻² P−2.36×10⁻³ P² (eV) (1)

The fitting function for bulk GaN is:

E_{g}=3.39+4.2×10⁻² P−1.8×10⁻³ P² (eV) (2)

See W. Shan et al., Journal of Applied Physics 85, 8505 (1999); and S. Strite and H. Morkoc, Journal of Vacuum Science & Technology B 10, 1237 (1992). Both the linear and second-order pressure coefficients of the GaN NWs (6.09×10⁻² and −2.36×10⁻³, respectively) are significantly larger than those reported for bulk GaN (4.2×10⁻² and −1.8×10⁻³, respectively). In order to determine the origin of this difference, larger “bulk-like” GaN micropillars were fabricated. The GaN microstructures/pillars were fabricated using the same two-step, top-down process and from the same GaN film as the GaN NWs, but with dimensions of ˜5×7×7 μm³ (an SEM image of the micropillars is shown in the inset of FIG. 7). The GaN micropillars were placed into the DAC for PL measurements; the bandgap of a single micropillar (squares) as a function of applied pressure is shown in FIG. 7. It can be seen that the GaN micropillars exhibit a similar bandgap vs. pressure relationship as the bulk GaN film previously reported. This result indicates the enhanced pressure coefficients for the GaN NWs is a nanoscale effect not observed at larger bulk-like dimensions. Therefore, although strain-induced tuning is observed at bulk-like dimensions, this nanoscale effect enables a significantly larger wavelength tuning range in GaN NWs than is possible with bulk-like GaN.

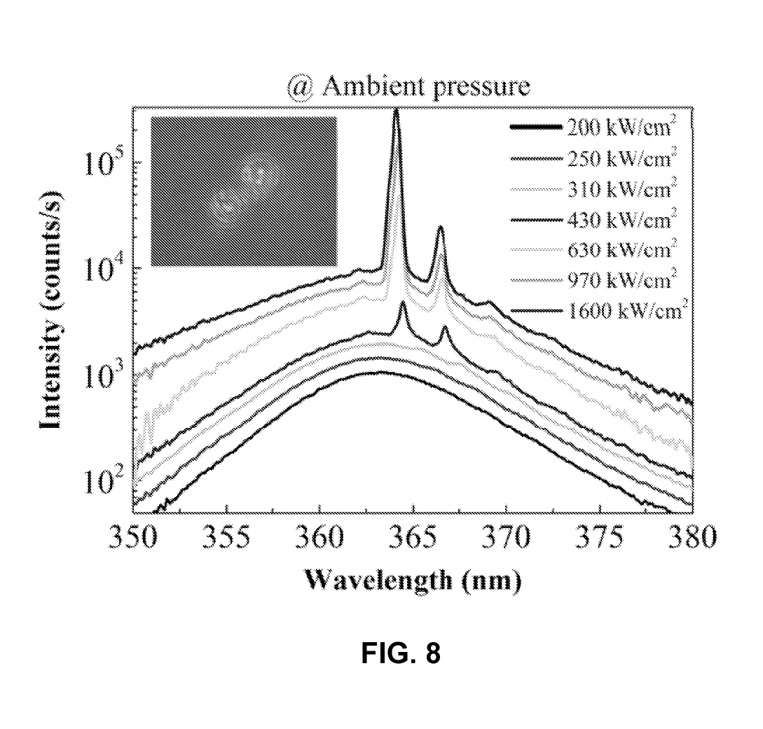

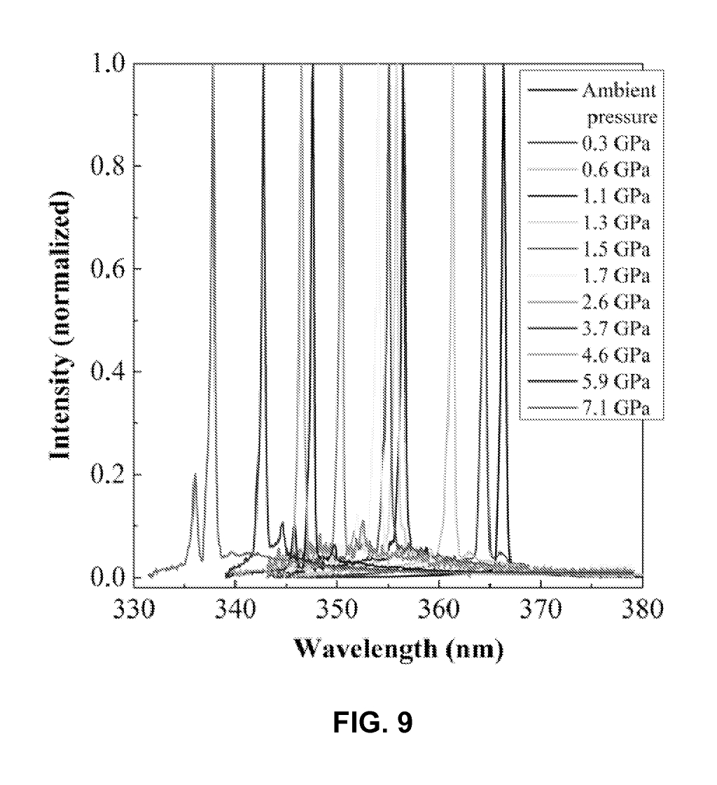

As seen in FIG. 8, as the pump power incident on the NWs was increased at ambient pressure, sharp emission peaks emerge from the relatively broad PL background, indicating the onset of lasing. The lasing is also confirmed by the CCD image (inset of FIG. 8) of coherent optical interference ring fringes formed from the lasing emission of the two end facets. Lasing emission was maintained as the applied pressure was increased on the NW from ambient to ˜7.1 GPa. The applied pressure induces a blue shift of the lasing spectra from ˜367 to 337 nm, representing a wide and continuous 30 nm range of spectral tuning, as seen in FIG. 9. This indicates dynamic spectral tuning of NW lasers via application of hydrostatic pressure. As described above, the volume of GaN is reduced when applying high pressure based on both Birch-Murnaghan equation of state and x-ray diffraction results, indicating ˜1% of lattice constant reduction when the pressure increases from ambient to ˜7 GPa. See M. Ueno et al., Physical Review \acute{B} 49, 14 (1994); H. Xia et al., Physical Review B 47, 12925 (1993); and Z. Dong and Y. Song, Applied Physics Letters 96, 151903 (2010). It is unlikely that the transverse or longitudinal modes of the GaN NW lasers are significantly modified by this minor volume shrinkage. Therefore, the lasing tuning of GaN NW lasers can be completely attributed to the bandgap shift.

Between 1 GPa and 2 GPa, the pressure was intentionally increased at smaller intervals to show that subnanometer resolution tuning of <0.5 nm can be easily achieved. According to Eq. (1), at the lower pressure regime of <2 GPa, fine tuning of ˜0.2 nm can be achieved by increasing the pressure ˜0.1 GPa. At a higher pressure regime of >4 GPa, even finer tuning of ˜0.1 nm can be achieved by increasing the pressure ˜0.1 GPa. Moreover, reversible lasing wavelength tuning was observed when the pressure was released, as long as the pressure remained below the phase transition pressure.

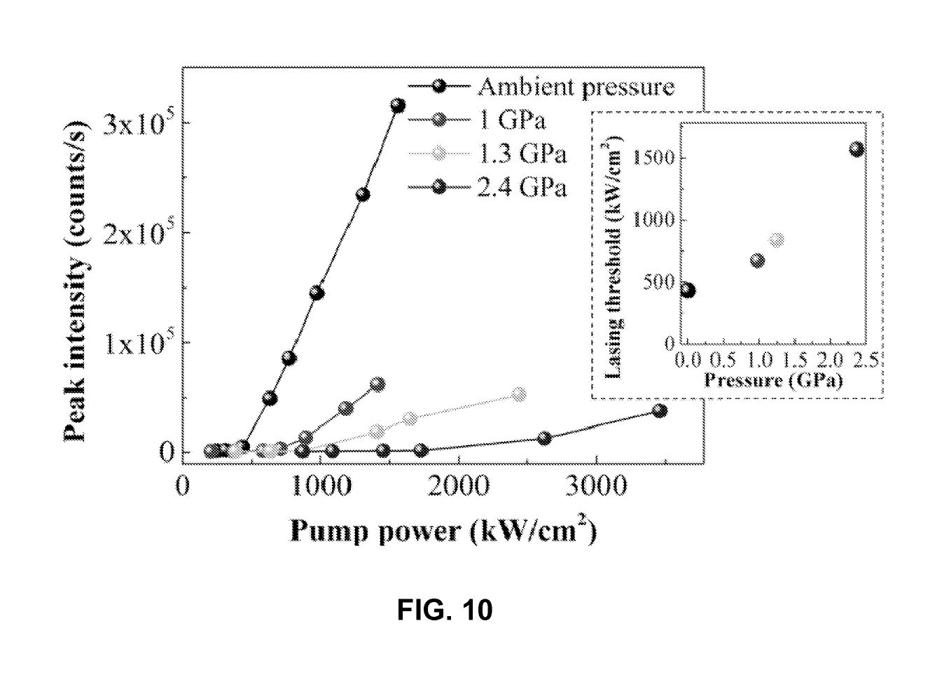

The lasing intensity decreased and the lasing threshold increased as the applied pressure increased. FIG. 10 plots the light out versus pump intensity at four different pressures. The lasing thresholds are indicated by the abrupt slope changes. The lasing thresholds show a gradual increase as the pressure increases, as summarized in the inset of FIG. 10, lasing is observed up to pressures ˜7 GPa, above which the higher thresholds destroy the NWs before the onset of lasing can be observed.

The threshold gain of semiconductor lasers depends on the cavity losses, facet reflectivities, and the mode confinement factor according to:

R² exp[2(g_{ch}Γ−α)L]=1 (3)

where R is the reflectivity of the laser cavity mirror (the same reflectivity is assumed for both facets of the NW laser), gₜₕ the threshold gain of GaN NW per unit length (the gain of NW is proportional to the pump intensity), Γ the mode confinement factor, α the cavity loss per unit length, and L the length of NW lasers. The pump intensity required to achieve enough gain to compensate the loss depends on the environmental refractive index which strongly affects the confinement factor as well as the facet reflectivity. At zero applied pressure, a ˜2-3 times increase in lasing threshold was experimentally observed when the GaN NWs were placed from air into silicone oil, due to the reduced refractive index contrast.

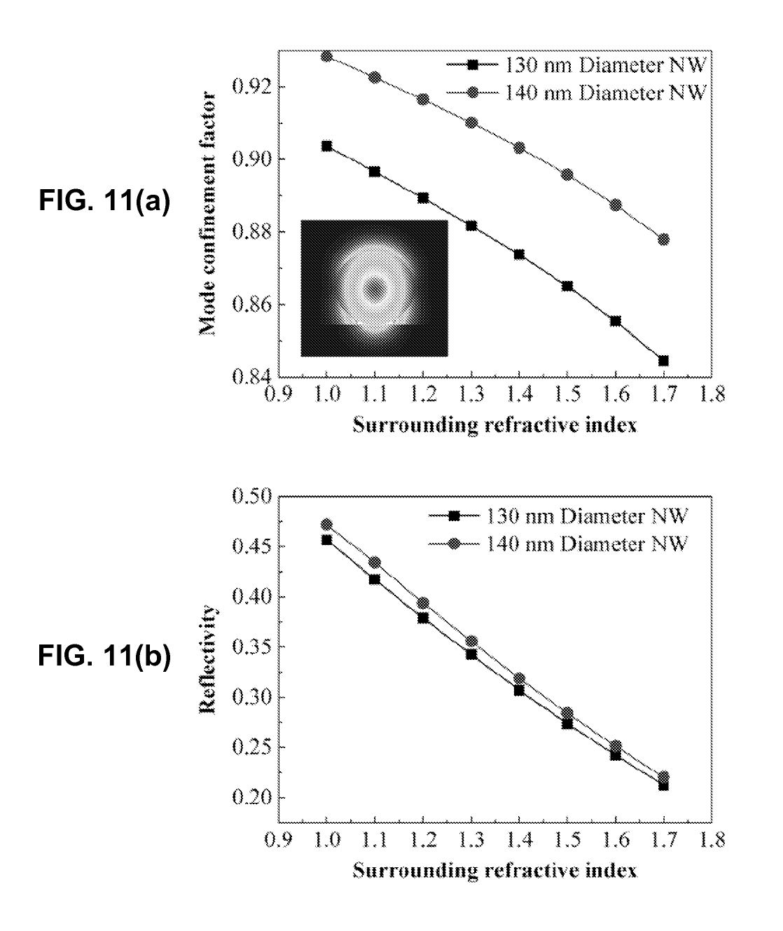

FIGS. 11(a) and (b) show finite-differential-time-domain (FDTD) simulations of the confinement factor and the NW end facet reflectivity, respectively, when the environmental refractive index changes, based on the method of Maslov et al. See A. V. Maslov and C. Z. Ning, Applied Physics Letters 83, 1237 (2003); and A. V. Maslov and C. Z. Ning, IEEE Journal of Quantum Electronics 40, 1389 (2004). The refractive index for GaN (2.8) used in the simulation was measured using ellipsometry of a GaN epilayer. See J. B. Wright et al., Applied Physics Letters 104, 041107 (2014). Although values for the pressure dependent refractive index of silicone oil (using 1.4 at ambient) could not be found, an increase of ˜20-30% (from ambient to 7 GPa) of its refractive index is expected based on the values reported for other liquids, such as water, rape-seed oil and methyl alcohol. See P. Chylek et al., Applied Optics 22, 2302 (1983); D. Pan et al., Nat Commun 5, 3919 (2014); K. Vedam and P. Limsuwan, The Journal of Chemical Physics 69, 4772 (1978); and A. J. Rostocki et al., Journal of Molecular Liquids 135, 120 (2007). GaN NWs with diameters of 130 nm and 140 nm were used in the simulation and the HE₁₁ fundamental mode was selected as the lasing mode. See Q. Li et al., Optics Express 20, 17873 (2012). The inset of FIG. 11(a) shows the electric field intensity profile of HE₁₁ mode supported in a 140 nm diameter GaN NW lying on a sapphire substrate. FIG. 11(a) shows that the confinement factor decreases as the environmental refractive index increases. Even more significantly, FIG. 11(b) shows that the end facet reflectivity is dramatically reduced from ˜0.47 to ˜0.21 when the refractive index increases for both NW diameters. Both of these two effects (the decrease in the mode confinement and facet reflectivity) are further enhanced because the refractive index of GaN slightly decreases (<3%) as pressure increases according to the Moss formula or Ravindra expression. See N. Bouarissa, Materials Chemistry and Physics 73, 51 (2002). The simulations only take into account the change of silicone oil because it is a much bigger effect compared with the change of GaN. It is also possible that the gain of GaN is changed as pressure is applied, but with a minor contribution because similar PL linewidths and intensities were observed as those shown in FIG. 6. Therefore, the threshold increase with increasing pressure can be explained by the decrease in confinement and end facet reflectivity resulting from a decreasing refractive index contrast.

Two methods can be used to mitigate the problem of increased laser threshold with increased applied pressure. First, gases, such as He and N₂, can be used instead of liquid as the pressure transmission medium, since the refractive index is lower for gases at both low and high pressures. Second, the NW end facets can be coated with a high reflectivity metal, such as aluminum, a low refractive index dielectric material, such as Al₂O₃, or a distributed Bragg reflector such that the facet reflectivity does not depend on environmental changes.

The present invention has been described as a method for semiconductor nano/microlaser tuning by strain engineering. It will be understood that the above description is merely illustrative of the applications of the principles of the present invention, the scope of which is to be determined by the claims viewed in light of the specification. Other variants and modifications of the invention will be apparent to those of skill in the art.

1. A method for tuning the lasing wavelength of a semiconductor nano/micro laser, comprising:
providing a III-V or II-VI compound semiconductor nano/micro laser having a direct bandgap; and
applying a mechanical strain to the semiconductor nano/microlaser to change the direct bandgap energy of the semiconductor and the lasing wavelength.

2. (canceled)

3. The method of claim 1, wherein the compound semiconductor comprises (Al)(In)(Ga)N, (Al)(In)(Ga)As, (Al)(In)(Ga)P, (Al)(In)(Ga)Sb, or ZnO.

4. The method of claim 3, wherein the compound semiconductor comprises GaN.

5. The method of claim 1, wherein the active area of the semiconductor nano/microlaser comprises a radial or axial heterostructure.

6. The method of claim 1, wherein the semiconductor nano/microlaser comprises a nano- or micro-wire, belt, column, rod, tube, ring, stripe, disc, or sheet.

7. The method of claim 1, wherein the semiconductor nano/microlaser has a cross-sectional dimension of less than 15 micrometers.

8. The method of claim 1, wherein the semiconductor nano/microlaser has a cross-sectional dimension of less than 500 nanometers.

9. The method of claim 1, wherein the semiconductor nano/microlaser has a length of greater than 300 nanometers.

10. The method of claim 9, wherein the semiconductor nano/microlaser has a length of less than 300 micrometers.

11. The method of claim 1, wherein the mechanical strain comprises hydrostatic pressure.

12. The method of claim 11, wherein the hydrostatic pressure is applied using a diamond anvil cell.

13. The method of claim 11, wherein the hydrostatic pressure is applied using a piston-cylinder device, multi-anvil cell, or embossing machine.

14. The method of claim 1, wherein the mechanical strain comprises tensile or compressive strain.

15. The method of claim 14, wherein the tensile or compressive strain is applied using a microelectromechanical or piezoelectric system.

16. The method of claim 14, wherein the tensile or compressive strain is applied using an external electric field.

17. The method of claim 14, wherein the tensile or compressive strain is applied using thermally induced expansion or contraction.

18. The method of claim 1, wherein the semiconductor nano/microlaser comprises a Fabry-Perot cavity.
